(19) United States
(12) Patent Application Publication
(10) Pub. No.: US 2024/0324423 A1
(43) Pub. Date: Sep. 26, 2024

(54) DISPLAY APPARATUS

(71) Applicant: Samsung Display Co., Ltd., Yongin-Si (KR)

(72) Inventor: Junhee Lee, Yongin-si (KR)

(21) Appl. No.: 18/423,299

(22) Filed: Jan. 26, 2024

(30) Foreign Application Priority Data
Mar. 24, 2023 (KR) 10-2023-0039051
Mar. 29, 2023 (KR) 10-2023-0041495

(51) Int. Cl. H10K 59/80; H10K 59/121; H10K 59/131

(52) U.S. Cl. CPC H10K 59/8792; H10K 59/121; H10K 59/131

(57) ABSTRACT

A display apparatus is disclosed that includes a substrate, a first planarization layer, first, second, and third light emitting elements, and a second planarization layer. The first planarization layer is disposed on the substrate. The first light-emitting element, the second light-emitting element, and the third light-emitting element are disposed on the first planarization layer and include a first emission region, a second emission region, and a third emission region, respectively, which emit light of different wavelengths. The second planarization layer is disposed between the first planarization layer and the first emission region. The second emission region does not overlap the second planarization layer.

### CROSS-REFERENCE TO RELATED APPLICATIONS

This application is based on and claims priority under 35 U.S.C. § 119 to Korean Patent Application Nos. 10-2023-0039051, filed on Mar. 24, 2023, and 10-2023-0041495, filed on Mar. 29, 2023, in the Korean Intellectual Property Office, the disclosures of which are incorporated by reference herein in their entirety.

### BACKGROUND

### 1. Field

One or more embodiments relate to a display apparatus, and more particularly, to a display apparatus with improved display quality.

### 2. Description of the Related Art

Organic light-emitting display apparatuses have self-emissive characteristics and, unlike liquid crystal display apparatuses, do not require a separate light source and, thus, may have reduced thickness and weight. In addition, organic light-emitting display apparatuses have high-quality characteristics such as low power consumption, high luminance, and high response speed.

### SUMMARY

One or more embodiments include a display apparatus with improved display quality by reducing a reflective color band phenomenon caused by asymmetrical reflection of external light. However, the embodiments are only examples, and the scope of the disclosure is not limited thereto.

Additional aspects will be set forth in part in the description which follows and, in part, will be apparent from the description, or may be learned by practice of the presented embodiments of the disclosure.

According to one or more embodiments, A display apparatus may include a substrate, a first planarization layer disposed on the substrate, a first light-emitting element, a second light-emitting element, and a third light-emitting element disposed on the first planarization layer and including a first emission region, a second emission region, and a third emission region, respectively, which emit light of different wavelengths, and a second planarization layer disposed between the first planarization layer and the first emission region, wherein the first emission region overlaps the second planarization layer and the second emission region does not overlap the second planarization layer.

In an embodiment, the second planarization layer is disposed between the first planarization layer and the third emission region.

In an embodiment, the display apparatus may further include first conductive lines disposed below the first planarization layer to overlap the first emission region and spaced apart from each other below the first emission region, and a conductive layer disposed below the first planarization layer to overlap the second emission region, wherein the second emission region covers the conductive layer.

In an embodiment, a first pixel electrode of the first light-emitting element may be disposed on an upper surface of the second planarization layer, and a second pixel electrode of the second light-emitting element may be disposed on an upper surface of the first planarization layer.

In an embodiment, a lower surface of the first pixel electrode may be in contact with the upper surface of the second planarization layer, and a lower surface of the second pixel electrode may be in contact with the upper surface of the first planarization layer.

In an embodiment, the first pixel electrode may include a first body portion overlapping the first emission region and a first contact portion extending from the first body portion, the second pixel electrode may include a second body portion overlapping the second emission region and a second contact portion extending from the second body portion, and an area of the second planarization layer below the first emission region may be greater than an area of the first body portion.

In an embodiment, a distance between an upper surface of the substrate and a lower surface of the first body portion may be greater than a distance between the upper surface of the substrate and a lower surface of the second body portion.

In an embodiment, the first contact portion of the first pixel electrode may extend along an inclined surface of the second planarization layer and may be disposed on the upper surface of the first planarization layer.

In an embodiment, the display apparatus may further include a pixel-defining film covering edges of each of the first body portion and the second body portion and having pixel openings that expose a central portion of the first body portion and the second body portion, respectively, the pixel-defining film may cover an edge of the second planarization layer.

In an embodiment, the second planarization layer may further include second conductive lines disposed below the first planarization layer to overlap the third emission region and spaced apart from each other below the third emission region.

In an embodiment, a third pixel electrode of the third light-emitting element may be disposed on the upper surface of the second planarization layer.

In an embodiment, the second planarization layer may include island patterns.

In an embodiment, a height of the first planarization layer may be equal to a height of the second planarization layer.

According to one or more embodiments, a display apparatus may include a substrate, a first planarization, a first light-emitting element, a second light-emitting element, and a third light-emitting element disposed on the first planarization layer and including a first emission region, a second emission region, and a third emission region, respectively, which emit light of different wavelengths, a second planarization layer including a first island pattern disposed between the first planarization layer and the first emission region and a second island pattern disposed between the first planarization layer and the third emission region, a first pixel electrode disposed on an upper surface of the first island pattern to overlap the first emission region, a second pixel electrode disposed on an upper surface of the first planarization layer to overlap the second emission region, and a third pixel electrode disposed on an upper surface of the second island pattern to overlap the third emission region.

In an embodiment, the display apparatus may further include first conductive lines disposed below the first planarization layer to overlap the first emission region, and spaced apart from each other below the first emission region, a conductive layer disposed below the first planarization layer to overlap the second emission region, and second conductive lines disposed below the first planarization layer to overlap the third emission region, and spaced apart from each other below the third emission region, and the second emission region may cover the conductive layer.

In an embodiment, a lower surface of the first pixel electrode may be in contact with the upper surface of the first island pattern, a lower surface of the second pixel electrode may be in contact with the upper surface of the first planarization layer, and a lower surface of the third pixel electrode may be in contact with the upper surface of the second island pattern.

In an embodiment, the first pixel electrode may include a first body portion overlapping the first emission region and a first contact portion extending from the first body portion, the second pixel electrode may include a second body portion overlapping the second emission region and a second contact portion extending from the second body portion, the third pixel electrode may include a third body portion overlapping the third emission region and a third contact portion extending from the third body portion, an area of the first island pattern may be greater than an area of the first body portion, and an area of the second island pattern may be greater than an area of the third body portion.

In an embodiment, a distance between an upper surface of the substrate and a lower surface of the first body portion may be greater than a distance between the upper surface of the substrate and a lower surface of the second body portion and may be equal to a distance between the upper surface of the substrate and a lower surface of the third body portion.

In an embodiment, an area of the third emission region may be greater than an area of the first emission region, an area of the third body portion may be greater than an area of the first body portion, and an area of the second island pattern may be greater than an area of the first island pattern.

In an embodiment, a distance between an edge of the first body portion and an edge of the first island pattern may be equal to a distance between an edge of the third body portion and an edge of the second island pattern.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 shows a light-emitting element provided in any one pixel of a display apparatus, and a pixel circuit connected thereto, according to an embodiment;

FIG. 3 is a schematic cross-sectional view of a display apparatus according to embodiments;

FIG. 4 is a schematic plan view of a part of pixel arrangement in a display region; and

FIG. 5 is a cross-sectional view of the display apparatus of FIG. 1 taken along line B-B′ of FIG. 4.

### DETAILED DESCRIPTION

Reference will now be made in detail to embodiments, examples of which are illustrated in the accompanying drawings, wherein like reference numerals refer to like elements throughout the present specification. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiment, it will be understood that although the terms “first,” “second,” etc. may be used herein to describe various components, these components should not be limited by these terms. These terms are only used to distinguish one component from another.

In the following embodiment, the expression of singularity in the present specification includes the expression of plurality unless clearly specified otherwise in context.

In the following embodiment, it will be further understood that the words “comprising,” “including,” and “having” (as well as their variations such as “comprises”) used herein specify the presence of stated features or components, but do not preclude the presence or addition of one or more other features or components.

In the following embodiment, it will be understood that when a layer, region, or component is connected to another layer, region, or component, the layers, regions or components may not only be directly connected, but may also be indirectly connected via another layer, region, or component therebetween. For example, in the present specification, when a layer, region, or component is electrically connected to another layer, region, or component, the layers, regions, or components may not only be directly electrically connected, but may also be indirectly electrically connected via another layer, region, or component therebetween.

In the following embodiment, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

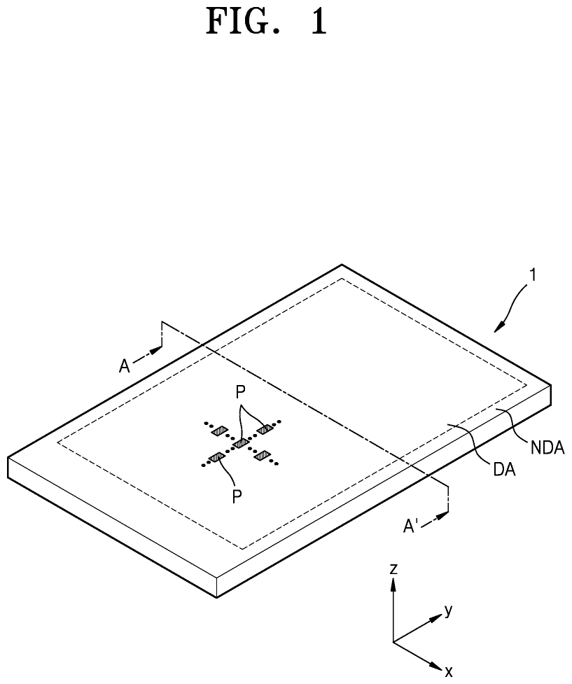

FIG. 1 is a schematic perspective view of a display apparatus according to an embodiment.

In an embodiment, a display apparatus 1 displays moving images or still images and may be used as display screens of various products such as televisions, laptops, monitors, billboards, or Internet of Things (IOTs) as well as portable devices such as mobile phones, smartphones, tablet personal computers (tablet PCs), mobile communication terminals, electronic notebooks, e-books, portable multimedia players (PMPs), navigation devices, or ultra-mobile PCs (UMPCs).

In addition, in an embodiment, the display apparatus 1 may be used in wearable devices such as smart watches, watch phones, glass-type displays, and head mounted displays (HMDs). Furthermore, in an embodiment, the display apparatus 1 may be used as a display for an instrument panel for vehicles, a center information display (CID) arranged on the center fascia or dashboard of vehicles, a room mirror display in lieu of a side-view mirror of vehicles, or a display arranged at the rear side of a front seat as an entertainment for a rear seat of vehicles. For convenience of explanation, FIG. 1 illustrates that the display apparatus 1 is used as a smartphone.

Referring to FIG. 1, the display apparatus 1 according to an embodiment may include a display region DA and a non-display region NDA located outside the display region DA. FIG. 1 illustrates that the display region DA has a substantially rectangular shape, but the disclosure is not limited thereto. The display region DA may have various shapes such as a circle, an ellipse, and a polygon.

The display region DA is a portion for displaying an image, and a plurality of pixels P may be arranged in the display region DA. Each of the pixels P may include a light-emitting element such as an organic light-emitting diode OLED. Each of the pixels P may emit, for example, red light, green light, blue light, or white light.

The display region DA may provide a certain image via light emitted from the pixels P. The pixel P in the present specification may be defined as an emission region emitting light of any one color among red, green, blue, or white, as described above.

The non-display region NDA is where the pixels P are not arranged, and may not provide an image. A printed circuit board including a power supply line and a driving circuit unit, each for driving the pixels P, or a terminal unit to which a driver integrated circuit (IC) is connected may be arranged in the non-display region NDA.

Hereinafter, as the display apparatus according to an embodiment, an organic light-emitting display apparatus is described as an example. However, the display apparatus of the disclosure is not limited thereto. For example, the display apparatus of the disclosure may be an inorganic light-emitting display apparatus (or inorganic electroluminescent (EL) display apparatus) or a quantum dot light-emitting display apparatus. For example, an emission layer included in a light-emitting element provided in the display apparatus may include an organic material or an inorganic material. In addition, quantum dots may be located on a path of light emitted from the emission layer.

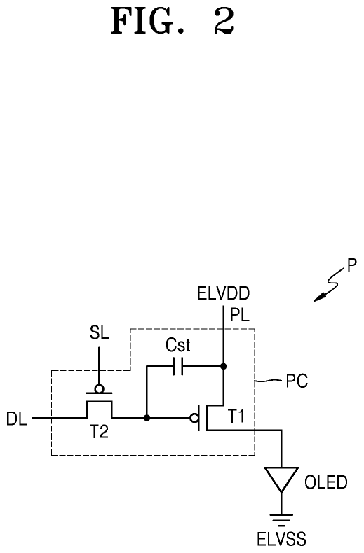

FIG. 2 shows a light-emitting element provided in any one pixel of a display apparatus, and a pixel circuit PC connected thereto, according to an embodiment.

Referring to FIG. 2, the organic light-emitting diode OLED which is a light-emitting element is connected to the pixel circuit PC. The pixel circuit PC may include a first thin-film transistor T1, a second thin-film transistor T2, and a storage capacitor Cst. The organic light-emitting diode OLED may emit, for example, red light, green light, or blue light, or may emit red light, green light, blue light, or white light.

The second thin-film transistor T2, as a switching thin-film transistor, is connected to a scan line SL and a data line DL, and may transmit a data voltage input from the data line DL to the first thin-film transistor T1 according to a switching voltage input from the scan line SL. The storage capacitor Cst is connected to the second thin-film transistor T2 and a driving voltage line PL, and may store a voltage corresponding to a difference between a voltage received from the second thin-film transistor T2 and a first power voltage ELVDD supplied to the driving voltage line PL.

The first thin-film transistor T1, as a driving thin-film transistor, is connected to the driving voltage line PL and the storage capacitor Cst, and may control a driving current flowing from the driving voltage line PL to the organic light-emitting diode OLED, according to a voltage value stored in the storage capacitor Cst. The organic light-emitting diode OLED may emit light having a certain luminance by the driving current. A common electrode (for example, cathode) of the organic light-emitting diode OLED may receive a second power voltage ELVSS.

FIG. 2 illustrates that the pixel circuit PC includes two thin-film transistors and one storage capacitor, but in another embodiment, the number of thin-film transistors or the number of storage capacitors may vary according to the design of the pixel circuit PC.

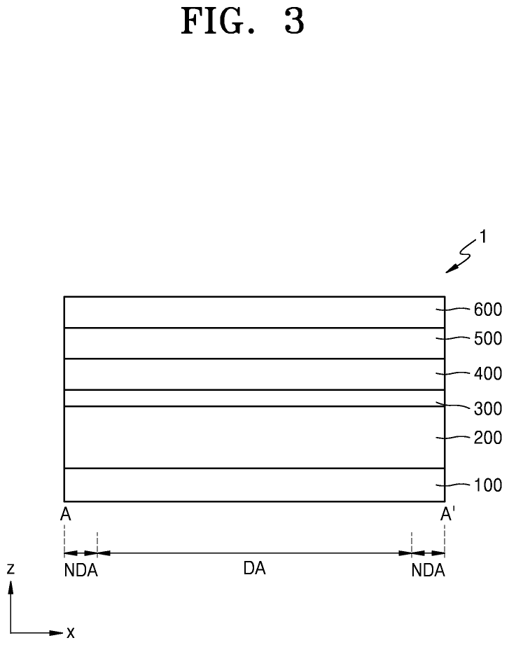

FIG. 3 is a schematic cross-sectional view of a display apparatus according to embodiments, and is a cross-sectional view of the display apparatus 1 taken along line A-A′ of FIG. 1.

Referring to FIG. 3, the display apparatus 1 according to an embodiment may include a substrate 100, a display layer 200, a low-reflection layer 300, a thin-film encapsulation layer 400, a touch sensor layer 500, and a reflection prevention layer 600.

The substrate 100 may include glass or polymer resin. For example, the polymer resin may include polyethersulfone, polyacrylate, polyether imide, polyethylene naphthalate, polyethylene terephthalate, polyphenylene sulfide, polyarylate, polyimide, polycarbonate, or cellulose acetate propionate. The substrate 100 including polymer resin may be flexible, rollable, or bendable. The substrate 100 may have a multilayer structure including a layer including polymer resin and an inorganic layer (not shown).

The display layer 200 may include an organic light-emitting diode which is a light-emitting element, a thin-film transistor electrically connected to the organic light-emitting diode, and insulating layers arranged therebetween.

The low-reflection layer 300 may be disposed on the display layer 200, and the thin-film encapsulation layer 400 may be disposed on the low-reflection layer 300. For example, the display layer 200 or the low-reflection layer 300 may be sealed with the thin-film encapsulation layer 400. The thin-film encapsulation layer 400 may include at least one inorganic film layer and at least one organic film layer. In some embodiments, the low-reflection layer 300 may be omitted.

In some embodiments, the display apparatus 1 may include an encapsulation substrate (not shown) formed of a glass material, instead of the thin-film encapsulation layer 400. The encapsulation substrate may be disposed on the display layer 200, and the display layer 200 may be arranged between the substrate 100 and the encapsulation substrate. A gap may exist between the encapsulation substrate and the display layer 200, and the gap may be filled with a filler.

The touch sensor layer 500 may be disposed on the thin-film encapsulation layer 400. The touch sensor layer 500 may detect an external input, for example, a touch of a finger or an object such as a stylus pen, such that the display apparatus 1 may obtain coordinate information corresponding to a touch location. The touch sensor layer 500 may include a touch electrode and trace lines connected to the touch electrode. The touch sensor layer 500 may detect an external input by using a mutual capacitance method or a self-capacitance method.

In an embodiment, the touch sensor layer 500 may be directly formed on the thin-film encapsulation layer 400. Alternatively, the touch sensor layer 500 may be separately formed and then adhered onto the thin-film encapsulation layer 400 by using an adhesive layer such as an optically-clear adhesive (OCA).

The reflection prevention layer 600 may be disposed on the touch sensor layer 500. The reflection prevention layer 600 may reduce reflectance of light (external light) incident toward the display apparatus 1.

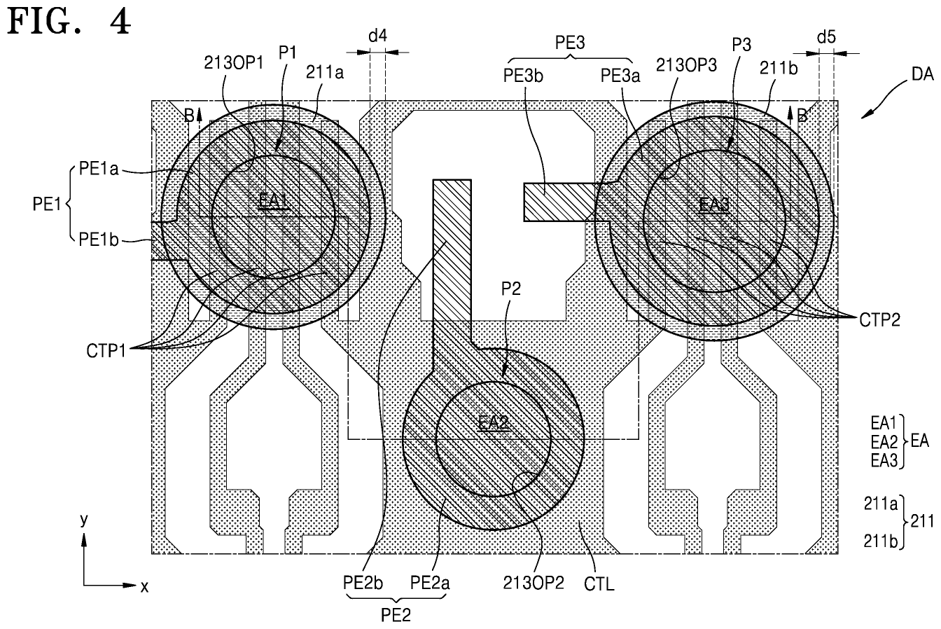

FIG. 4 is a schematic plan view of a part of pixel arrangement in a display region. For convenience of explanation, FIG. 4 illustrates only some of components included in the display apparatus 1. Hereinafter, referring to FIGS. 1 and 4, a pixel arrangement structure of the display apparatus 1 according to an embodiment is briefly described.

Referring to FIGS. 1 and 4, the display apparatus 1 may include the plurality of pixels P arranged in the display region DA, and the plurality of pixels P may include a first pixel P1, a second pixel P2, and a third pixel P3, which emit different colors. For example, the first pixel P1 may emit red light, the second pixel P2 may emit green light, and the third pixel P3 may emit blue light. However, the disclosure is not limited thereto. For example, the first pixel P1 may emit blue light, the second pixel P2 may emit green light, and the third pixel P3 may emit red light, and various modifications may be made.

In an embodiment, the first pixel P1, the second pixel P2, and the third pixel P3 may have a circular planar shape. In another embodiment, the first pixel P1, the second pixel P2, and the third pixel P3 may have various planar shapes such as a polygon, a polygon with rounded corners, and an ellipse.

In an embodiment, the sizes of the first pixel P1, the second pixel P2, and the third pixel P3 may be different from each other. For example, the size of the second pixel P2 may be less than the sizes of the first pixel P1 and the third pixel P3, and the size of the third pixel P3 may be greater than the size of the first pixel P1. In another embodiment, the sizes of the first pixel P1, the second pixel P2, and the third pixel P3 may be substantially the same, and various modifications may be made.

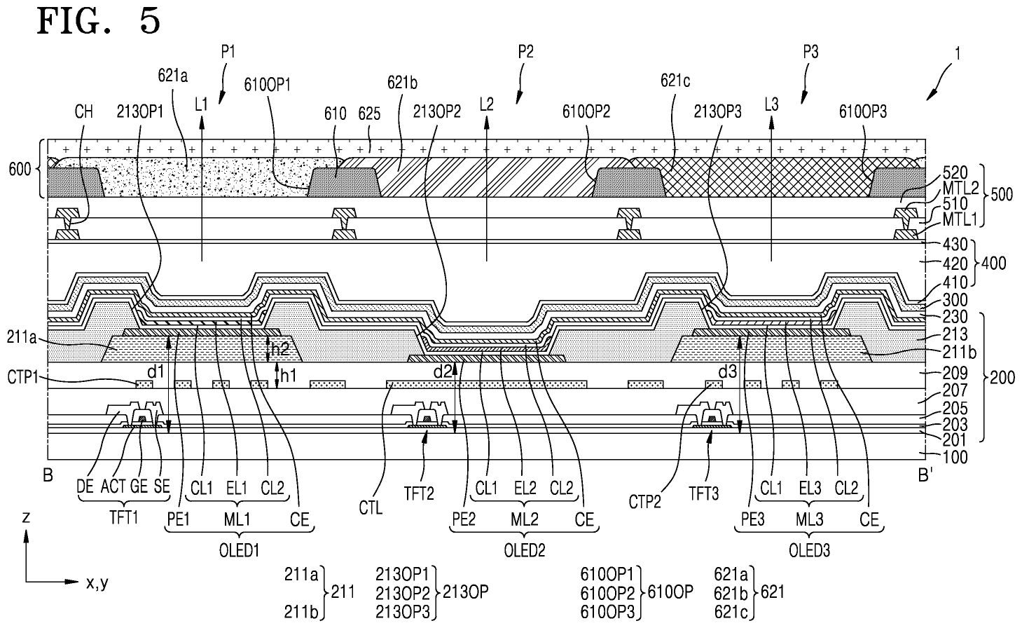

In the present specification, the sizes of the first pixel P1, the second pixel P2, and the third pixel P3 may each refer to the size of an emission region EA of a light-emitting element implementing each pixel, and the emission region EA may be defined by a pixel opening 213OP of a pixel-defining film 213 (see FIG. 5). For example, a first emission region EA1 may emit red light, a second emission region EA2 may emit green light, and a third emission region EA3 may emit blue light, but the disclosure is not limited thereto.

In an embodiment, the first pixel P1, the second pixel P2, and the third pixel P3 may be arranged in a pixel arrangement structure having a shape shown in FIG. 4. However, the disclosure is not limited thereto. For example, the first pixel P1, the second pixel P2, and the third pixel P3 may be arranged in various pixel arrangement structures such as a pentile (PENTILE™) structure, a stripe structure, a mosaic structure, and a delta structure.

FIG. 5 is a cross-sectional view of the display apparatus of FIG. 1 taken along line B-B′ of FIG. 4. Hereinafter, referring to FIGS. 4 and 5, components of the display apparatus 1 according to an embodiment are described in detail according to a stacking order.

Referring to FIGS. 4 and 5, the display apparatus 1 according to an embodiment may include the substrate 100, the display layer 200, the low-reflection layer 300, the thin-film encapsulation layer 400, the touch sensor layer 500, and the reflection prevention layer 600.

The display layer 200 may include first to third organic light-emitting diodes OLED1, OLED2, and OLED3 and thin-film transistors TFT1, TFT2, and TFT3, and may include a buffer layer 201, a gate insulating layer 203, an interlayer insulating layer 205, a via insulating layer 207, a first planarization layer 209, a second planarization layer 211, and the pixel-defining film 213, which are insulating layers. Each of the thin-film transistors TFT1, TFT2, and TFT3 may include a semiconductor layer ACT, a gate electrode GE, a source electrode SE, and a drain electrode DE. The first organic light-emitting diode OLED1 may include a first pixel electrode PE1, a first middle layer ML1, and a common electrode CE, and may be referred to as a first light-emitting element. The second organic light-emitting diode OLED2 may include a second pixel electrode PE2, a second middle layer ML2, and the common electrode CE, and may be referred to as a second light-emitting element. The third organic light-emitting diode OLED3 may include a third pixel electrode PE3, a third middle layer ML3, and the common electrode CE, and may be referred to as a third light-emitting element.

The buffer layer 201 may be disposed on the substrate 100, and thus, may reduce or block penetration of foreign substances, moisture, or external air from a lower portion of the substrate 100 and provide a flat surface on the substrate 100. The buffer layer 201 may include an inorganic material such as an oxide or a nitride, an organic material, or an organic/inorganic composite, and may formed as a single-layered or multilayer structure of the inorganic material and the organic material. A barrier layer (not shown) may be further included between the substrate 100 and the buffer layer 201 to block penetration of external air. The buffer layer 201 may include silicon oxide (SiO₂) or silicon nitride (SiN_{X}).

The thin-film transistors TFT1, TFT2, and TFT3 may be disposed on the buffer layer 201. Each of the thin-film transistors TFT1, TFT2, and TFT3 may include the semiconductor layer ACT, the gate electrode GE, the source electrode SE, and the drain electrode DE. The thin-film transistors TFT1, TFT2, and TFT3 may be respectively connected to and drive the first to third organic light-emitting diodes OLED1, OLED2, and OLED3.

The semiconductor layer ACT may be disposed on the buffer layer 201 and may include polysilicon. Alternatively, the semiconductor layer ACT may include amorphous silicon. Alternatively, the semiconductor layer ACT may include an oxide of at least one material selected from the group including indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer ACT may include a channel region, and a source region and a drain region, which are doped with impurities.

The gate electrode GE, the source electrode SE, and the drain electrode DE may be formed of various conductive materials. The gate electrode GE may include at least one of molybdenum, aluminum, copper, and titanium. For example, the gate electrode GE may have a single layer of molybdenum, or may have a three-layer structure including a molybdenum layer, an aluminum layer, and a molybdenum layer. The source electrode SE and the drain electrode DE may each include at least one material selected from the group including copper, titanium, and aluminum. For example, the source electrode SE and the drain electrode DE may each have a three-layer structure including a titanium layer, an aluminum layer, and a titanium layer.

Meanwhile, in order to secure insulation between the semiconductor layer ACT and the gate electrode GE, the gate insulating layer 203 including an inorganic material such as silicon oxide, silicon nitride, or silicon oxynitride may be arranged between the semiconductor layer ACT and the gate electrode GE. Furthermore, the interlayer insulating layer 205 including silicon oxide, silicon nitride, or silicon oxynitride may be disposed above the gate electrode GE, and the source electrode SE and the drain electrode DE may be disposed on the interlayer insulating layer 205. As such, an insulating film including an inorganic material may be formed by suing chemical vapor deposition (CVD) or atomic layer deposition (ALD). The same is applied to the following embodiments.

The via insulating layer 207 may be disposed on the thin-film transistors TFT1, TFT2, and TFT3. The via insulating layer 207 may include an organic insulating material and may provide a flat upper surface. The via insulating layer 207 may include a general purpose polymer such as photosensitive polyimide, polyimide, polystyrene (PS), polycarbonate (PC), benzocyclobutene (BCB), hexamethyldisiloxane (HMDSO), polymethylmethacrylate (PMMA), or polystyrene (PS), a polymer derivative having a phenolic group, an acrylic polymer, an imide-based polymer, an aryl ether-based polymer, an amide-based polymer, a fluorine-based polymer, a p-xylene-based polymer, or a vinyl alcohol-based polymer.

First conductive lines CTP1, a conductive layer CTL, and second conductive lines CTP2 may be disposed on the via insulating layer 207. In an embodiment, the first conductive lines CTP1 may overlap the first emission region EA1, the conductive layer CTL may overlap the second emission region EA2, and the second conductive lines CTP2 may overlap the third emission region EA3.

The first conductive lines CTP1 may be disposed above the via insulating layer 207 and below the first planarization layer 209 to overlap the first emission region EA1. The first conductive lines CTP1 may be apart from each other within the first emission region EA1. For example, the first conductive lines CTP1 may extend in a y direction and may be apart from each other in an x direction. In an embodiment, the first conductive lines CTP1 may be lines for transmitting various signals or voltages to the thin-film transistor TFT1. For example, the first conductive lines CTP1 may include a data line for transmitting a data voltage to the thin-film transistor TFT1.

The conductive layer CTL may be disposed above the via insulating layer 207 and below the first planarization layer 209 to overlap the second emission region EA2. The conductive layer CTL may entirely cover the second emission region EA2. For example, the conductive layer CTL may have an area greater than that of the second emission region EA2. In addition, the conductive layer CTL may have an area greater than that of a second body portion PE2a of the second pixel electrode PE2. Accordingly, the conductive layer CTL may block external light from entering from an upper portion of the display apparatus 1 to the thin-film transistor TFT2 or various lines under the conductive layer CTL, thereby preventing defects of the thin-film transistor TFT2 and the lines. In an embodiment, the conductive layer CTL may transmit the first power voltage ELVDD to the thin-film transistors TFT1, TFT2, and TFT3.

The second conductive lines CTP2 may be disposed above the via insulating layer 207 and below the first planarization layer 209 to overlap the third emission region EA3. The second conductive lines CTP2 may be apart from each other within the third emission region EA3. For example, the second conductive lines CTP2 may extend in the y direction and may be apart from each other in the x direction. In an embodiment, the second conductive lines CTP2 may be lines for transmitting various signals or voltages to the thin-film transistor TFT3. For example, the second conductive lines CTP2 may include a data line for transmitting a data voltage to the thin-film transistor TFT3.

The first conductive lines CTP1, the conductive layer CTL, and the second conductive lines CTP2 may be formed of various conductive materials. For example, the first conductive lines CTP1, the conductive layer CTL, and the second conductive lines CTP2 may each include at least one material selected from the group including copper, titanium, and aluminum. For example, the first conductive lines CTP1, the conductive layer CTL, and the second conductive lines CTP2 may each have a three-layer structure including a titanium layer, an aluminum layer, and a titanium layer.

In an embodiment, the first conductive lines CTP1, the conductive layer CTL, and the second conductive lines CTP2 may be formed substantially at the same time. For example, after a metal layer is formed entirely on the via insulating layer 207, the metal layer is etched to form the first conductive lines CTP1, the conductive layer CTL, and the second conductive lines CTP2.

The first planarization layer 209 may be disposed on the first conductive lines CTP1, the conductive layer CTL, and the second conductive lines CTP2. The first planarization layer 209 may cover the first conductive lines CTP1, the conductive layer CTL, and the second conductive lines CTP2, on the via insulating layer 207. The first planarization layer 209 may include an organic insulating material. The first planarization layer 209 may be arranged entirely in the display region DA. The first planarization layer 209 may be arranged entirely in the first emission region EA1, the second emission region EA2, and the third emission region EA3.

The second planarization layer 211 may be disposed on the first planarization layer 209. The second planarization layer 211 may be disposed on the first planarization layer 209 to overlap only some of the first emission region EA1, the second emission region EA2, and the third emission region EA3. For example, the second planarization layer 211 may not be formed in the second emission region EA2 overlapping the conductive layer CTL, and may be formed to correspond to only the first and third emission regions EA1 and EA3 overlapping the first and second conductive lines CTP1 and CTP2. In other words, the second planarization layer 211 may overlap the first emission region EA1 and the third emission region EA3 and may not overlap the second emission region EA2.

In the first planarization layer 209, a first portion overlapping the conductive layer CTL having a large area may provide a substantially flat upper surface, but a second portion overlapping the first conductive lines CTP1 and a third portion overlapping the second conductive lines CTP2 may each provide a more or less uneven upper surface. In this case, when the second planarization layer 211 is not arranged and the first to third pixel electrodes PE1, PE2, and PE3 are disposed directly on an upper surface of the first planarization layer 209, the flatness of each of the first pixel electrode PE1 overlapping the first conductive lines CTP1 and the third pixel electrode PE3 overlapping the second conductive lines CTP2 may decrease, and accordingly, external light is asymmetrically reflected by the first pixel electrode PE1 and the third pixel electrode PE3, and a reflective color band phenomenon may occur in which asymmetric color separation occurs around the reflected light. Meanwhile, when the first planarization layer 209 is formed thick or the second planarization layer 211 is formed entirely in the display region DA to increase the flatness of each of the first pixel electrode PE1 and the third pixel electrode PE3, the first to third pixel electrodes PE1, PE2, and PE3 may shrink as the volume of an organic insulating layer increases. In order to prevent this, in the display apparatus 1 according to an embodiment, as the second planarization layer 211 is not formed in the second emission region EA2 (region with high flatness of the upper surface of the first planarization layer 209) overlapping the conductive layer CTL and is formed to correspond only to the first and third emission regions EA1 and EA3 (regions with low flatness of the upper surface of the first planarization layer 209) overlapping the first and second conductive lines CTP1 and CTP2, a reflective color band phenomenon is prevented or reduced and simultaneously, an increase of the volume of an organic insulating layer is minimized, such that a phenomenon in which the first to third pixel electrodes PE1, PE2, and PE3 shrink may be prevented or reduced.

In an embodiment, the second planarization layer 211 may include island patterns arranged apart from each other. For example, the second planarization layer 211 may include a first island pattern 211a overlapping the first emission region EA1 and a second island pattern 211b overlapping the third emission region EA3. The first island pattern 211a and the second island pattern 211b are described in detail in the following description.

In an embodiment, a height h1 of the first planarization layer 209 and a height h2 of the second planarization layer 211 may be substantially the same. For example, the height h1 of the first planarization layer 209 and the height h2 of the second planarization layer 211 may each be about 1 μm to about 2 μm. In another embodiment, the height h1 of the first planarization layer 209 and the height h2 of the second planarization layer 211 may be different from each other.

In an embodiment, the first planarization layer 209 and the second planarization layer 211 may be formed by using the same material. In addition, the first planarization layer 209 and the second planarization layer 211 may be formed by different processes. For example, the first planarization layer 209 may be formed by coating an organic insulating material on the via insulating layer 207 to cover the first conductive lines CTP1, the conductive layer CTL, and the second conductive lines CTP2. Next, a first contact hole may be formed in the first planarization layer 209. In addition, after an organic layer is formed by coating an organic insulating material on the first planarization layer 209, a portion of the organic layer is removed to form the second planarization layer 211 including the first and second island patterns 211a and 211b. In addition, when necessary, a portion of the organic layer may be removed and simultaneously, a second contact hole may be formed in the second planarization layer 211. In this case, when the first contact hole and the second contact hole overlap each other, the second contact hole may be formed to be larger than the first contact hole. For example, the first contact hole of the first planarization layer 209 and the second contact hole of the second planarization layer 211 may each have a structure having a stepwise cross-section.

In the first emission region EA1, the first organic light-emitting diode OLED1 may be disposed on the first island pattern 211a of the second planarization layer 211. In the second emission region EA2, the second organic light-emitting diode OLED2 may be disposed on the first planarization layer 209. In the third emission region EA3, the third organic light-emitting diode OLED3 may be disposed on the second island pattern 211b of the second planarization layer 211.

The first organic light-emitting diode OLED1 may include the first pixel electrode PE1, the first middle layer ML1, and the common electrode CE. The second organic light-emitting diode OLED2 may include the second pixel electrode PE2, the second middle layer ML2, and the common electrode CE. The third organic light-emitting diode OLED3 may include the third pixel electrode PE3, the third middle layer ML3, and the common electrode CE.

The first pixel electrode PE1 may be a reflective electrode. In this case, the first pixel electrode PE1 may include a reflective film including silver (Ag), magnesium (Mg), aluminum (Al), platinum (Pt), palladium (Pd), gold (Au), nickel (Ni), neodymium (Nd), iridium (Ir), chromium (Cr), and a compound thereof, and a transparent or semi-transparent conductive layer formed on the reflective film. The transparent or semi-transparent conductive layer may include at least one material selected from the group including indium tin oxide (ITO), indium zinc oxide (IZO), zinc oxide (ZnO), indium oxide (In₂O₃), indium gallium oxide (IGO), and aluminum zinc oxide (AZO). For example, the first pixel electrode PE1 may have a structure of a stack of ITO/Ag/ITO.

At least a portion of the first pixel electrode PE1 may be disposed on an upper surface of the first island pattern 211a of the second planarization layer 211 to overlap the first emission region EA1. In an embodiment, a lower surface of the first pixel electrode PE1 may be in contact with the upper surface of the first island pattern 211a of the second planarization layer 211.

In an embodiment, the first pixel electrode PE1 may include a first body portion PE1a and a first contact portion PE1b extending from the first body portion PE1a. The first body portion PE1a may overlap the entire first emission region EA1. For example, the area of the first body portion PE1a may be greater than the area of the first emission region EA1.

In an embodiment, the first island pattern 211a of the second planarization layer 211 may overlap the entire first body portion PE1a of the first pixel electrode PE1. For example, the area of the first island pattern 211a may be greater than the area of the first body portion PE1a. In detail, the area of the upper surface of the first island pattern 211a may be greater than the area of a lower surface of the first body portion PE1a. In other words, the entire first body portion PE1a may be disposed on the upper surface of the first island pattern 211a.

In an embodiment, the first body portion PE1a may have a planar shape corresponding to the first emission region EA1, and the first island pattern 211a may have a planar shape corresponding to the first body portion PE1a. FIG. 4 illustrates that each of the first emission region EA1, the first body portion PE1a, and the first island pattern 211a has a circular planar shape, but the disclosure is not limited thereto. In another embodiment, each of the first emission region EA1, the first body portion PE1a, and the first island pattern 211a may have various planar shapes such as a polygon, a polygon with rounded corners, and an ellipse.

The first contact portion PE1b may extend from the first body portion PE1a. In an embodiment, the first contact portion PE1b may extend along an inclined surface of the first island pattern 211a, and an end portion of the first contact portion PE1b may be disposed on the upper surface of the first planarization layer 209. The end portion of the first contact portion PE1b may be electrically connected to the source electrode SE or the drain electrode DE of the thin-film transistor TFT1 via the via insulating layer 207 and the contact hole formed in the first planarization layer 209. Accordingly, the first pixel electrode PE1 may be electrically connected to the thin-film transistor TFT1.

The second pixel electrode PE2 may be a reflective electrode. At least a portion of the second pixel electrode PE2 may be disposed on the upper surface of the first planarization layer 209 to overlap the second emission region EA2. In an embodiment, a lower surface of the second pixel electrode PE2 may be in contact with the upper surface of the first planarization layer 209.

In an embodiment, the second pixel electrode PE2 may include the second body portion PE2a and a second contact portion PE2b extending from the second body portion PE2a. The second body portion PE2a may overlap the entire second emission region EA2. For example, the area of the second body portion PE2a may be greater than the area of the second emission region EA2. In an embodiment, the second body portion PE2a may have a planar shape corresponding to the second emission region EA2.

The second contact portion PE2b may extend from the second body portion PE2a. In an embodiment, the second contact portion PE2b may be disposed on the upper surface of the first planarization layer 209. An end portion of the second contact portion PE2b may be electrically connected to the source electrode SE or the drain electrode DE of the thin-film transistor TFT2 via the via insulating layer 207 and the contact hole formed in the first planarization layer 209. Accordingly, the second pixel electrode PE2 may be electrically connected to the thin-film transistor TFT2.

The third pixel electrode PE3 may be a reflective electrode. At least a portion of the third pixel electrode PE3 may be disposed on an upper surface of the second island pattern 211b of the second planarization layer 211 to overlap the third emission region EA3. In an embodiment, a lower surface of the third pixel electrode PE3 may be in contact with the upper surface of the second island pattern 211b of the second planarization layer 211.

In an embodiment, the third pixel electrode PE3 may include a third body portion PE3a and a third contact portion PE3b extending from the third body portion PE3a. The third body portion PE3a may overlap the entire third emission region EA3. For example, the area of the third body portion PE3a may be greater than the area of the third emission region EA3.

In an embodiment, the second island pattern 211b of the second planarization layer 211 may overlap the entire third body portion PE3a of the third pixel electrode PE3. For example, the area of the second island pattern 211b may be greater than the area of the third body portion PE3a. In detail, the area of the upper surface of the second island pattern 211b may be greater than the area of a lower surface of the third body portion PE3a. In other words, the entire third body portion PE3a may be disposed on the upper surface of the second island pattern 211b.

the third body portion PE3a may have a planar shape corresponding to the third emission region EA3, and the second island pattern 211b may have a planar shape corresponding to the third body portion PE3a.

The third contact portion PE3b may extend from the third body portion PE3a. In an embodiment, the third contact portion PE3b may extend along an inclined surface of the second island pattern 211b, and an end portion of the third contact portion PE3b may be disposed on the upper surface of the first planarization layer 209. The end portion of the third contact portion PE3b may be electrically connected to the source electrode SE or the drain electrode DE of the thin-film transistor TFT3 via the via insulating layer 207 and the contact hole formed in the first planarization layer 209. Accordingly, the third pixel electrode PE3 may be electrically connected to the thin-film transistor TFT3.

In an embodiment, as the first pixel electrode PE1 and the third pixel electrode PE3 are disposed on an upper surface of the second planarization layer 211, and the second pixel electrode PE2 is disposed on the upper surface of the first planarization layer 209, some of the first to third pixel electrodes PE1, PE2, and PE3 may have different levels. For example, a distance d1 between an upper surface of the substrate 100 and the lower surface of the first body portion PE1a of the first pixel electrode PE1 may be greater than a distance d2 between the upper surface of the substrate 100 and a lower surface of the second body portion PE2a of the second pixel electrode PE2. For example, a distance d3 between the upper surface of the substrate 100 and the lower surface of the third body portion PE3a of the third pixel electrode PE3 may be greater than the distance d2 between the upper surface of the substrate 100 and the lower surface of the second body portion PE2a of the second pixel electrode PE2. For example, the distance d1 between the upper surface of the substrate 100 and the lower surface of the first body portion PE1a of the first pixel electrode PE1 may be substantially the same as the distance d3 between the upper surface of the substrate 100 and the lower surface of the third body portion PE3a of the third pixel electrode PE3.

In an embodiment, the areas of the first to third emission regions EA1, EA2, and EA3 may be different from each other. For example, the area of the second emission region EA2 may be less than the areas of the first emission region EA1 and the third emission region EA3, and the area of the third emission region EA3 may be greater than the area of the first emission region EA1. In this case, the areas of the first to third body portions PE1a, PE2a, and PE3a of the first to third pixel electrodes PE1, PE2, and PE3 may be different from each other. For example, the area of the second body portion PE2a may be less than the areas of the first body portion PE1a and the third body portion PE3a, and the area of the third body portion PE3a may be greater than the area of the first body portion PE1a. In addition, the areas of the first and second island patterns 211a and 211b of the second planarization layer 211 may be different from each other. For example, the area of the second island pattern 211b may be greater than the area of the first island pattern 211a.

In an embodiment, a distance d4 between an edge of the first body portion PE1a and an edge of the first island pattern 211a may be substantially the same as a distance d5 between an edge of the third body portion PE3a and an edge of the second island pattern 211b. For example, the distance d4 between the edge of the first body portion PE1a and the edge of the first island pattern 211a and the distance d5 between the edge of the third body portion PE3a and the edge of the second island pattern 211b may each be about 1.5 μm to about 2.5 μm. In another embodiment, the distance d4 between the edge of the first body portion PE1a and the edge of the first island pattern 211a may be different from the distance d5 between the edge of the third body portion PE3a and the edge of the second island pattern 211b.

The pixel-defining film 213 may be disposed on the first to third pixel electrodes PE1, PE2, and PE3. The pixel-defining film 213 may have pixel openings 213OP that respectively expose central portions of the first to third pixel electrodes PE1, PE2, and PE3. For example, the pixel-defining film 213 may have a first pixel opening 213OP1 that exposes the central portion of the first body portion PE1a of the first pixel electrode PE1, a second pixel opening 213OP2 that exposes the central portion of the second body portion PE2a of the second pixel electrode PE2, and a third pixel opening 213OP3 that exposes the central portion of the third body portion PE3a of the third pixel electrode PE3.

In an embodiment, the pixel-defining film 213 may cover an edge of the second planarization layer 211. For example, the pixel-defining film 213 may cover the edge of the first island pattern 211a, and the first pixel opening 213OP1 may expose a central portion of the first island pattern 211a. The pixel-defining film 213 may cover the edge of the second island pattern 211b, and the second pixel opening 213OP2 may expose a central portion of the second island pattern 211b.

The pixel-defining film 213 may include an organic insulating material. Alternatively, the pixel-defining film 213 may include an inorganic insulating material such as silicon nitride, silicon oxynitride, or silicon oxide. Alternatively, the pixel-defining film 213 may include an organic insulating material and an inorganic insulating material. In an embodiment, the pixel-defining film 213 may include a light-blocking material and may be black. The light-blocking material may include resin or paste including carbon black, carbon nanotubes, or black dye, metal particles such as nickel, aluminum, molybdenum, and an alloy thereof, metal oxide particles (for example, chromium oxide), or metal nitride particles (for example, chromium nitride). When the pixel-defining film 213 includes the light-blocking material, reflection of external light by metal structures disposed under the pixel-defining film 213 may be reduced. However, the disclosure is not limited thereto. In another embodiment, the pixel-defining film 213 may not include a light-blocking material, but may include a light-transmissive organic insulating material.

The first middle layer ML1 including a first common layer CL1, a first emission layer EL1, and a second common layer CL2 may be disposed on the first pixel electrode PE1 and the pixel-defining film 213. The second middle layer ML2 including the first common layer CL1, a second emission layer EL2, and the second common layer CL2 may be disposed on the second pixel electrode PE2 and the pixel-defining film 213. The third middle layer ML3 including the first common layer CL1, a third emission layer EL3, and the second common layer CL2 may be disposed on the third pixel electrode PE3 and the pixel-defining film 213.

The first emission layer EL1 may be arranged in the first pixel opening 213OP1 of the pixel-defining film 213. The first emission layer EL1 may be a low-molecular-weight or polymer organic material including a fluorescent or phosphorescent material capable of emitting blue light, green light, or red light. Alternatively, the first emission layer EL1 may be an inorganic material including quantum dots. In particular, a quantum dot refers to a crystal of a semiconductor compound and may include any material capable of emitting light of various emission wavelengths depending on the size of the crystal. The quantum dot may include, for example, a Group III-VI semiconductor compound, a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof. For example, the first emission layer EL1 may emit red light.

The second emission layer EL2 may be arranged in the second pixel opening 213OP2 of the pixel-defining film 213. The second emission layer EL2 may be a low-molecular-weight or polymer organic material including a fluorescent or phosphorescent material capable of emitting blue light, green light, or red light. Alternatively, the second emission layer EL2 may be an inorganic material including quantum dots. For example, the second emission layer EL2 may emit green light.

The third emission layer EL3 may be arranged in the third pixel opening 213OP3 of the pixel-defining film 213. The third emission layer EL3 may be a low-molecular-weight or polymer organic material including a fluorescent or phosphorescent material capable of emitting blue light, green light, or red light. Alternatively, the third emission layer EL3 may be an inorganic material including quantum dots. For example, the third emission layer EL3 may emit blue light.

The first common layer CL1 and the second common layer CL2 may be disposed respectively below and on the first to third emission layers EL1, EL2, and EL3. The first common layer CL1 may include, for example, a hole transport layer (HTL), or may include a hole transport layer and a hole injection layer (HIL). The second common layer CL2 may include, for example, an electron transport layer (ETL), or may include an electron transport layer and an electron injection layer (EIL). In an embodiment, the second common layer CL2 may not be provided.

The first to third emission layers EL1, EL2, and EL3 may be arranged in respective pixels to respectively correspond to the first to third pixel openings 213OP1, 213OP2, and 213OP3 of the pixel-defining film 213, whereas the first common layer CL1 and the second common layer CL2 may each be integrally formed to entirely cover the substrate 100. In other words, the first common layer CL1 and the second common layer CL2 may each be integrally formed to entirely cover the display region DA of the substrate 100.

The common electrode CE may be a cathode which is an electron injection electrode. The common electrode CE may include a conductive material having a low work function. For example, the common electrode CE may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), ytterbium (Yb), or an alloy thereof. For example, the common electrode CE may be AgMg or AgYb. Alternatively, the common electrode CE may further include a layer such as ITO, IZO, ZnO or In₂O₃ on the (semi-)transparent layer including the above-described material.

In an embodiment, the display apparatus 1 may further include a capping layer 230 disposed on the first to third organic light-emitting diodes OLED1, OLED2, and OLED3. The capping layer 230 may serve to increase the luminescence efficiency of the first to third organic light-emitting diodes OLED1, OLED2, and OLED3 according to the principle of constructive interference. The capping layer 230 may include, for example, a material having a refractive index of 1.6 or more with respect to light having a wavelength of 589 nm.

The capping layer 230 may be an organic capping layer including an organic material, an inorganic capping layer including an inorganic material, or a composite capping layer including an organic material and an inorganic material. For example, the capping layer 230 may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be optionally substituted with a substituent including O, N, S, Se, Si, F, Cl, Br, I, or any combination thereof.

The low-reflection layer 300 may be disposed on the capping layer 230. Since the capping layer 230 may be disposed on the first to third organic light-emitting diodes OLED1, OLED2, and OLED3, the low-reflection layer 300 may be disposed on the first to third organic light-emitting diodes OLED1, OLED2, and OLED3. The low-reflection layer 300 may include an inorganic material having low reflectance, and in an embodiment, may include a metal or a metal oxide. When the low-reflection layer 300 includes a metal, for example, the low-reflection layer 300 may include ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof. In addition, when the low-reflection layer 300 includes a metal oxide, for example, the low-reflection layer 300 may include SiO₂, TiO₂, ZrO₂, Ta₂O₅, HfO₂, Al₂O₃, ZnO, Y₂O₃, BcO, MgO, PbO₂, WO₃, SiNx, LiF, CaF₂, MgF₂, CdS, or a combination thereof.

In an embodiment, the inorganic material included in the low-reflection layer 300 may have an absorption coefficient (k) of at least 0.5 and not more than 4.0 (0.5≤k≤4.0). In addition, the inorganic material included in the low-reflection layer 300 may have a refractive index (n) of 1 or more (n≥1.0).

The low-reflection layer 300 induces destructive interference between light incident to the inside of the display apparatus 1 and light reflected by a metal disposed below the low-reflection layer 300, thereby reducing external light reflectance. Therefore, display quality and visibility of the display apparatus 1 may be improved by reducing the external light reflectance of the display apparatus 1 via the low-reflection layer 300.

FIG. 5 illustrates a structure in which the low-reflection layer 300 is disposed on the entire surface of the substrate 100 like the common electrode CE and the capping layer 230, but the disclosure is not limited thereto. In another embodiment, the low-reflection layer 300 may be patterned and provided for each pixel. In this case, the low-reflection layer 300 may be patterned to correspond to the emission region EA of each pixel, and the area of the low-reflection layer 300 may be equal to or greater than that of the emission region EA.

The thin-film encapsulation layer 400 may be disposed on the low-reflection layer 300. The thin-film encapsulation layer 400 may include at least one inorganic film layer and at least one organic film layer. For example, the thin-film encapsulation layer 400 may include a first inorganic encapsulation layer 410, an organic encapsulation layer 420, and a second inorganic encapsulation layer 430, which are sequentially stacked.

The first inorganic encapsulation layer 410 and the second inorganic encapsulation layer 430 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The first inorganic encapsulation layer 410 and the second inorganic encapsulation layer 430 may each have a single-layered or multilayer structure including the above-described inorganic insulating material.

The organic encapsulation layer 420 may relieve internal stress of the first inorganic encapsulation layer 410 or the second inorganic encapsulation layer 430. The organic encapsulation layer 420 may include a polymer-based material. The polymer-based material may include polyethylene terephthalate, polyethylene naphthalate, polycarbonate, polyimide, polyethylenesulfonate, polyoxymethylene, polyarylate, hexamethyldisiloxane, acrylic resin (for example, polymethyl methacrylate or polyacrylic acid), or any combination thereof.

The organic encapsulation layer 420 may be formed by coating a material having flowability and including monomers, and then reacting the monomers to combine and form a polymer by using heat or light such as ultraviolet rays. Alternatively, the organic encapsulation layer 420 may be formed by coating a polymer material.

Even when cracks occur in the thin-film encapsulation layer 400 due to the above-described multilayer structure, the thin-film encapsulation layer 400 may allow the cracks not to be connected between the first inorganic encapsulation layer 410 and the organic encapsulation layer 420 or between the organic encapsulation layer 420 and the second inorganic encapsulation layer 430. Accordingly, formation of a path through which external moisture or oxygen penetrates into the display region DA may be prevented or minimized.

In an embodiment, when the thin-film encapsulation layer 400 is disposed on the first to third organic light-emitting diodes OLED1, OLED2, and OLED3, the substrate 100 may include polymer resin. However, the disclosure is not limited thereto.

The touch sensor layer 500 may be disposed on the thin-film encapsulation layer 400. The touch sensor layer 500 may include a first conductive layer MTL1, a first touch insulating layer 510, a second conductive layer MTL2, and a second touch insulating layer 520. The first conductive layer MTL1 may be disposed directly on the thin-film encapsulation layer 400. In this case, the first conductive layer MTL1 may be disposed directly on the second inorganic encapsulation layer 430 of the thin-film encapsulation layer 400. However, the disclosure is not limited thereto.

In addition, the touch sensor layer 500 may include an insulating film (not shown) arranged between the first conductive layer MTL1 and the thin-film encapsulation layer 400. The insulating film may be disposed on the second inorganic encapsulation layer 430 of the thin-film encapsulation layer 400 to flatten a surface on which the first conductive layer MTL1 or the like is disposed. In this case, the first conductive layer MTL1 may be disposed directly on the insulating film. The insulating film may include an inorganic insulating material such as silicon oxide (SiO₂), silicon nitride (SiN_{X}), or silicon oxynitride (SiON). Alternatively, the insulating film may include an organic insulating material.

In an embodiment, the first touch insulating layer 510 may be disposed on the first conductive layer MTL1. The first touch insulating layer 510 may include an inorganic material or organic material. When the first touch insulating layer 510 includes an inorganic material, the first touch insulating layer 510 may include at least one material selected from the group including silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the first touch insulating layer 510 includes an organic material, the first touch insulating layer 510 may include at least one material selected from the group including acrylic resin, methacrylic resin, polyisoprene, vinyl-based resin, epoxy-based resin, urethane-based resin, cellulose-based resin, and perylene-based resin.

In an embodiment, the second conductive layer MTL2 may be disposed on the first touch insulating layer 510. The second conductive layer MTL2 may function as a sensor that detects a user's touch input. The first conductive layer MTL1 may function as a connector that connects the patterned second conductive layer MTL2 in one direction. In an embodiment, both the first conductive layer MTL1 and the second conductive layer MTL2 may function as a sensor. In this case, the first conductive layer MTL1 and the second conductive layer MTL2 may be electrically connected with each other through a contact hole CH. As such, as both the first conductive layer MTL1 and the second conductive layer MTL2 function as a sensor, resistance of the touch electrode is reduced, and thus, a user's touch input may be rapidly detected.

In an embodiment, the first conductive layer MTL1 and the second conductive layer MTL2 may each have, for example, a mesh structure such that light emitted from the first to third organic light-emitting diodes OLED1, OLED2, and OLED3 may pass therethrough. In this case, the first conductive layer MTL1 and the second conductive layer MTL2 may be arranged not to overlap the first to third emission regions EA1, EA2, and EA3 of the first to third organic light-emitting diodes OLED1, OLED2, and OLED3.

The first conductive layer MTL1 and the second conductive layer MTL2 may include a metal layer or a transparent conductive layer. The metal layer may include molybdenum (Mo), silver (Ag), titanium (Ti), copper (Cu), aluminum (Al), and an alloy thereof. The transparent conductive layer may include a transparent conductive oxide such as indium tin oxide (ITO), indium zinc oxide (IZO), zinc oxide (ZnO), or indium tin zinc oxide (ITZO). In addition, the transparent conductive layer may include a conductive polymer such as PEDOT, a metal nanowire, a carbon nanotube, or graphene.

In an embodiment, the second touch insulating layer 520 may be disposed on the second conductive layer MTL2. The second touch insulating layer 520 may include an inorganic material or an organic material. When the second touch insulating layer 520 includes an inorganic material, the second touch insulating layer 520 may include at least one material selected from the group including silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. When the second touch insulating layer 520 includes an organic material, the second touch insulating layer 520 may include at least one material selected from the group including acrylic resin, methacrylic resin, polyisoprene, vinyl-based resin, epoxy-based resin, urethane-based resin, cellulose-based resin, and perylene-based resin.

The reflection prevention layer 600 may be disposed on the touch sensor layer 500. The reflection prevention layer 600 may include a light-blocking layer 610 and a color filter layer 621. In an embodiment, the reflection prevention layer 600 may further include an overcoat layer 625 disposed on the light-blocking layer 610 and the color filter layer 621.

The light-blocking layer 610 may include a material capable of blocking light. For example, the light-blocking layer 610 may include an organic material having a high light absorption rate. The light-blocking layer 610 may include a black pigment or a black dye. The light-blocking layer 610 may include a photosensitive organic material, and may include, for example, a colorant such as a pigment or a dye.

The light-blocking layer 610 includes an opening 610OP overlapping the emission region EA. The opening 610OP may include first to third openings 610OP1, 610OP2, and 610OP3 respectively corresponding to the first to third organic light-emitting diodes OLED1, OLED2, and OLED3. The emission region EA may be defined by the pixel opening 213OP of the pixel-defining film 213, and in an embodiment, the opening 610OP of the light-blocking layer 610 may overlap the pixel opening 213OP of the pixel-defining film 213, and the width of the opening 610OP of the light-blocking layer 610 may be greater than the width of the pixel opening 213OP of the pixel-defining film 213.

A body portion of the light-blocking layer 610 including the opening 610OP may overlap a body portion of the pixel-defining film 213. For example, the body portion of the light-blocking layer 610 may overlap only the body portion of the pixel-defining film 213. The body portion of the light-blocking layer 610 is distinct from the opening 610OP of the light-blocking layer 610 and refers to a portion having a certain volume (thickness). Likewise, the body portion of the pixel-defining film 213 is distinct from the pixel opening 213OP of the pixel-defining film 213 and refers to a portion having a certain volume.

The color filter layer 621 may include first to third color filters 621a, 621b, and 621c of different colors respectively corresponding to the first to third organic light-emitting diodes OLED1, OLED2, and OLED3.

In an embodiment, the first to third color filters 621a, 621b, and 621c may be respectively arranged in the first to third openings 610OP1, 610OP2, and 610OP3 of the light-blocking layer 610. In an embodiment, the first to third color filters 621a, 621b, and 621c may have a color corresponding to light emitted from the first to third organic light-emitting diodes OLED1, OLED2, and OLED3, respectively. In an embodiment, when the first organic light-emitting diode OLED1 emits red light, the first color filter 621a may be a red color filter, when the second organic light-emitting diode OLED2 emits green light, the second color filter 621b may be a green color filter, and when the third organic light-emitting diode OLED3 emits blue light, the third color filter 621c may be a blue color filter. The light-blocking layer 610 may be arranged between neighboring color filters and may be arranged to surround an edge of each of the pixels P1, P2, and P3.

The overcoat layer 625 may be disposed on the light-blocking layer 610 and the color filter layer 621. The overcoat layer 625 is a colorless light-transmissive layer that does not have a color in a visible light band, and may flatten an upper surface of the light-blocking layer 610 and an upper surface of the color filter layer 621. The overcoat layer 625 may include a colorless light-transmissive organic material such as acrylic resin, and may be covered with window (not shown). The window may include a transparent (light-transmissive) material. For example, the window may include a glass substrate or a polymer substrate.

As described above, according to an embodiment, a display apparatus with improved display quality may be implemented by reducing a reflective color band phenomenon caused by asymmetrical reflection of external light. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first planarization layer disposed on the substrate;
a first light-emitting element, a second light-emitting element, and a third light-emitting element disposed on the first planarization layer and including a first emission region, a second emission region, and a third emission region, respectively, which emit light of different wavelengths; and
a second planarization layer disposed between the first planarization layer and the first emission region,
wherein the first emission region overlaps the second planarization layer and the second emission region does not overlap the second planarization layer.

2. The display apparatus of claim 1, wherein the second planarization layer is disposed between the first planarization layer and the third emission region.

3. The display apparatus of claim 1, further comprising:
first conductive lines disposed below the first planarization layer to overlap the first emission region and spaced apart from each other below the first emission region; and
a conductive layer disposed below the first planarization layer to overlap the second emission region,
wherein the second emission region covers the conductive layer.

4. The display apparatus of claim 1, wherein a first pixel electrode of the first light-emitting element is disposed on an upper surface of the second planarization layer, and
a second pixel electrode of the second light-emitting element is disposed on an upper surface of the first planarization layer.

5. The display apparatus of claim 4, wherein a lower surface of the first pixel electrode is in contact with the upper surface of the second planarization layer, and
a lower surface of the second pixel electrode is in contact with the upper surface of the first planarization layer.

6. The display apparatus of claim 4, wherein the first pixel electrode comprises a first body portion overlapping the first emission region and a first contact portion extending from the first body portion,
the second pixel electrode comprises a second body portion overlapping the second emission region and a second contact portion extending from the second body portion, and
an area of the second planarization layer below the first emission region is greater than an area of the first body portion.

7. The display apparatus of claim 6, wherein a distance between an upper surface of the substrate and a lower surface of the first body portion is greater than a distance between the upper surface of the substrate and a lower surface of the second body portion.

8. The display apparatus of claim 6, wherein the first contact portion of the first pixel electrode extends along an inclined surface of the second planarization layer and is disposed on the upper surface of the first planarization layer.

9. The display apparatus of claim 6, further comprising a pixel-defining film covering edges of each of the first body portion and the second body portion and having a first pixel opening and a second pixel opening that expose a central portion of the first body portion and the second body portion, respectively,
wherein the pixel-defining film covers an edge of the second planarization layer.

10. The display apparatus of claim 2, further comprising second conductive lines disposed below the first planarization layer to overlap the third emission region and spaced apart from each other below the third emission region.

11. The display apparatus of claim 10, wherein a third pixel electrode of the third light-emitting element is disposed on the upper surface of the second planarization layer.

12. The display apparatus of claim 1, wherein the second planarization layer comprises island patterns.

13. The display apparatus of claim 1, wherein a height of the first planarization layer is equal to a height of the second planarization layer.

14. A display apparatus comprising:
a substrate;
a first planarization layer disposed on the substrate;
a first light-emitting element, a second light-emitting element, and a third light-emitting element disposed on the first planarization layer and including a first emission region, a second emission region, and a third emission region, respectively, which emit light of different wavelengths; and
a second planarization layer comprising a first island pattern disposed between the first planarization layer and the first emission region and a second island pattern disposed between the first planarization layer and the third emission region;
a first pixel electrode disposed on an upper surface of the first island pattern to overlap the first emission region;
a second pixel electrode disposed on an upper surface of the first planarization layer to overlap the second emission region; and
a third pixel electrode disposed on an upper surface of the second island pattern to overlap the third emission region.

15. The display apparatus of claim 14, further comprising: first conductive lines disposed below the first planarization layer to overlap the first emission region, and spaced apart from each other below the first emission region;
a conductive layer disposed below the first planarization layer to overlap the second emission region; and
second conductive lines disposed below the first planarization layer to overlap the third emission region, and spaced apart from each other below the third emission region,
wherein the second emission region covers the conductive layer.

16. The display apparatus of claim 14, wherein a lower surface of the first pixel electrode is in contact with the upper surface of the first island pattern,
a lower surface of the second pixel electrode is in contact with the upper surface of the first planarization layer, and
a lower surface of the third pixel electrode is in contact with the upper surface of the second island pattern.

17. The display apparatus of claim 14, wherein the first pixel electrode comprises a first body portion overlapping the first emission region and a first contact portion extending from the first body portion,
the second pixel electrode comprises a second body portion overlapping the second emission region and a second contact portion extending from the second body portion,
the third pixel electrode comprises a third body portion overlapping the third emission region and a third contact portion extending from the third body portion,
an area of the first island pattern is greater than an area of the first body portion, and
an area of the second island pattern is greater than an area of the third body portion.

18. The display apparatus of claim 17, wherein a distance between an upper surface of the substrate and a lower surface of the first body portion is greater than a distance between the upper surface of the substrate and a lower surface of the second body portion and is equal to a distance between the upper surface of the substrate and a lower surface of the third body portion.

19. The display apparatus of claim 17, wherein an area of the third emission region is greater than an area of the first emission region,
an area of the third body portion is greater than an area of the first body portion, and
an area of the second island pattern is greater than an area of the first island pattern.

20. The display apparatus of claim 17, wherein a distance between an edge of the first body portion and an edge of the first island pattern is equal to a distance between an edge of the third body portion and an edge of the second island pattern.
